(19) United States
(12) Patent Application Publication
(10) Pub. No.: US 2025/0239975 A1
(43) Pub. Date: Jul. 24, 2025

(54) MULTI-MODE NONLINEAR JUNCTION DETECTOR

(71) Applicant: U.S. Army DEVCOM, Army Research Laboratory, Adelphi, MD (US)

(72) Inventors: Gregory J. Mazzaro, Charleston, SC (US); Kyle A. Gallagher, Silver Spring, MD (US); Kelly D. Sherbondy, Burke, VA (US); Jonathan W. Owen, Lawrence, KS (US); Aizaz K Salik, Springfield, VA (US)

(21) Appl. No.: 18/421,246

(22) Filed: Jan. 24, 2024

(51) Int. Cl. H03F 1/32; H03D 7/16; H03F 3/24

(52) U.S. Cl. CPC H03F 1/3252; H03D 7/165; H03F 3/245; H03F 2200/294; H03F 2200/451

(57) ABSTRACT

An apparatus uses a probe signal to generate a reflected signal from a target object for detecting the target object. Embodiments of the apparatus may operate in at least one of linear, harmonic, intermodulation, and cross-modulation modes. In some embodiments, the user may select between the four aforementioned modes of detection. Some embodiments disclosed herein, when operating in the harmonic mode or the cross-modulation mode, switch between banks of harmonically-related filters to stitch together a wideband nonlinear target response. In some embodiments disclosed herein, diplexers are implemented as absorptive filters to minimize system-generated harmonics. In some embodiments disclosed herein that are capable of operating in the cross-modulation mode, separate transmitters are implemented to minimize system-generated distortion.

### GOVERNMENT INTEREST

The embodiments herein may be manufactured, used, and/or licensed by or for the United States Government without the payment of royalties thereon.

### BACKGROUND

### Technical Field

The embodiments herein generally relate to apparatus for detecting nonlinear junctions.

### Description of the Related Art

Apparatus for detecting manmade devices containing electronic circuits have been proposed in the prior art. Such devices permit the detection of target devices, such as radios or mobile phones for example, in order to, for example, detect the presence of hostile communication devices in a military application or to detect personal electronic devices in order to help locate persons in an emergency or disaster such as an avalanche or an earthquake. Such apparatuses transmit a radio frequency (RF) probe signal and detect a reflected signal reflected by the target manmade device. There is a continuing need to improve the capabilities, the resistance to clutter, and the detection range of apparatuses or devices used for the detection of target manmade devices.

### SUMMARY

The embodiments disclosed herein are apparatuses or devices used for the detection of target objects or targets-of-interest that may include target manmade devices. The target manmade devices, also referred to as target devices herein for convenience, include features that cause the reflected signal Rx to have a detectable change with respect to the probe or transmitted signal Tx. Such features are referred to herein as nonlinear junctions. An example of such features may be a semiconductor device junction, for example a p-n junction, in the electronic circuitry in the target device. An example of a detectable change in the reflected signal Rx with respect to the probe or transmitted signal Tx is the inclusion of a frequency in the reflected signal Rx that was not present, or was insignificant, in the transmitted signal Tx.

Another embodiment provides an apparatus for detection of one or more target objects, the apparatus comprising an antenna structure; at least one transmitter communicating with the antenna structure, the at least one transmitter being configured to generate a transmitted signal that is transmitted by the antenna structure; and at least one receiver communicating with the antenna structure, the at least one receiver being configured to receive a received signal emanating from the one or more target objects in response to the transmitted signal and that is received by the antenna structure, wherein the at least one transmitter comprises: a radio frequency source configured to output a radio frequency source output signal to a transmit signal chain that begins with the radio frequency source and ends with the antenna structure, the transmit signal chain providing a transmit signal path from the radio frequency source to the antenna structure for a transmit signal, the transmit signal chain providing for signal communication between the radio frequency source and the antenna structure, wherein the source output signal is amplified with a gain needed to generate an antenna input transmit signal that is provided to the antenna structure; at least one power amplifier provided in the transmit signal chain and configured to amplify the source output signal to provide at least a portion of the gain needed to generate the antenna input transmit signal that is provided to the antenna structure to thereby generate the transmitted signal, wherein the power amplifier has an input signal and an output signal; and at least one bank of low-pass filters comprising a plurality of low-pass filters provided such that the transmit signal path in the transmit signal chain can be selectively routed through a selected one of the plurality of low-pass filters, each of the plurality of low-pass filters being configured to filter the transmit signal in the transmit signal path between the power amplifier and the antenna structure when it is selected such that the transmit signal path is routed through it, wherein the at least one receiver comprises: a radio frequency detector having at least one input configured to receive a detector input signal derived from the received signal received by the antenna structure, wherein a receive signal chain provides a receive signal path from the antenna structure to the detector for a receive signal based on the received signal received by the antenna structure; at least one low-noise amplifier provided in the receive signal chain and configured to amplify a low-noise amplifier input signal derived from the received signal received by the antenna structure, the low-noise amplifier producing a low-noise amplifier output signal, which is provided to the receive signal chain such that the detector input signal can be derived from the low-noise amplifier output signal; and at least one bank of high-pass filters comprising a plurality of high-pass filters provided such that the receive signal path in the receive signal chain can be selectively routed through a selected one of the plurality of high-pass filters, each of the plurality of high-pass filters being configured to filter the receive signal in the receive signal path between the low-noise amplifier and the antenna structure when it is selected such that the receive signal path is routed through it, wherein each of the plurality of high-pass filters corresponds to a corresponding one of the plurality of low-pass filters, wherein each of the plurality of high-pass filters and the corresponding one of the plurality of low-pass filters form a pair of corresponding high-pass and low-pass filters, wherein each of the plurality of low-pass filters passes frequencies in a corresponding transmit band of a plurality of transmit bands, wherein each of the plurality of high-pass filters effectively rejects frequencies in the corresponding transmit band of the plurality of transmit bands corresponding to the corresponding one of the plurality of low-pass filters such that the frequency of the transmitted signal that is transmitted by the antenna structure can be scanned over the plurality of transmit bands by switching from one pair of corresponding high-pass and low-pass filters corresponding to one of the plurality of transmit bands to another pair of corresponding high-pass and low-pass filters corresponding to another one of the plurality of transmit bands.

Another embodiment provides an apparatus for detection of one or more target objects, the apparatus comprising an antenna structure; a plurality of transmitters communicating with the antenna structure, each of the plurality of transmitters being configured to generate a transmitted signal that is transmitted by the antenna structure such that a plurality of transmitted signals are transmitted by the antenna structure; and at least one receiver communicating with the antenna structure, the at least one receiver being configured to receive a received signal emanating from the one or more target objects in response to the plurality of transmitted signals and that is received by the antenna structure, wherein the apparatus operates in a cross-modulation mode, wherein each of the plurality of transmitters comprises: a radio frequency source configured to output a radio frequency source output signal to a transmit signal chain that begins with the radio frequency source and ends with the antenna structure, the transmit signal chain providing a transmit signal path from the radio frequency source to the antenna structure for a transmit signal, the transmit signal chain providing for signal communication between the radio frequency source and the antenna structure, wherein the source output signal is amplified with a gain needed to generate an antenna input transmit signal that is provided to the antenna structure; and at least one power amplifier provided in the transmit signal chain and configured to amplify the source output signal to provide at least a portion of the gain needed to generate the antenna input transmit signal that is provided to the antenna structure to thereby generate a corresponding one of the plurality of transmitted signals, wherein the at least one receiver comprises: a radio frequency detector having at least one input configured to receive a detector input signal derived from the received signal received by the antenna structure, wherein a receive signal chain provides a receive signal path from the antenna structure to the detector for a receive signal based on the received signal received by the antenna structure; and at least one low-noise amplifier provided in the receive signal chain and configured to amplify a low-noise amplifier input signal derived from the received signal received by the antenna structure, the low-noise amplifier producing a low-noise amplifier output signal, which is provided to the receive signal chain such that the detector input signal can be derived from the low-noise amplifier output signal, wherein each of the plurality of transmitters has a radio frequency source output signal that is of a different frequency compared to other transmitters of the plurality of transmitters such that each of the plurality of transmitted signals has a frequency that is different from other transmitted signals of the plurality of transmitted signals and that corresponds to the radio frequency source output signal frequency of a corresponding one of the plurality of transmitters.

The antenna structure may comprise a plurality of transmitter antennas and a receiver antenna, wherein each of the plurality of transmitter antennas is energized by a corresponding one of the plurality of transmitters to transmit a corresponding one of the plurality of transmitted signals, and wherein the receiver antenna communicates with the receive signal chain and provides an antenna output receive signal to the receive signal path of the receiver based on the received signal received by the receiver antenna.

Another embodiment provides an apparatus for detection of one or more target objects, the apparatus comprising an antenna structure; at least one transmitter communicating with the antenna structure, the at least one transmitter being configured to generate a transmitted signal that is transmitted by the antenna structure; and at least one receiver communicating with the antenna structure, the at least one receiver being configured to receive a received signal emanating from the one or more target objects in response to the transmitted signal and that is received by the antenna structure, wherein the at least one transmitter comprises: a radio frequency source configured to output a radio frequency source output signal to a transmit signal chain that begins with the radio frequency source and ends with the antenna structure, the transmit signal chain providing a transmit signal path from the radio frequency source to the antenna structure for a transmit signal, the transmit signal chain providing for signal communication between the radio frequency source and the antenna structure, wherein the source output signal is amplified with a gain needed to generate an antenna input transmit signal that is provided to the antenna structure; at least one power amplifier provided in the transmit signal chain and configured to amplify the source output signal to provide at least a portion of the gain needed to generate the antenna input transmit signal that is provided to the antenna structure to thereby generate the transmitted signal, wherein the power amplifier has an input signal and an output signal; and at least one low-pass filter provided in the transmit signal path between the power amplifier and the antenna structure such that the transmit signal path in the transmit signal chain can be routed through the low-pass filter, the low-pass filter being configured to filter undesirable frequencies out of the transmit signal in the transmit signal path traveling to the antenna structure, wherein the low-pass filter is an absorptive filter that squelches the undesirable frequencies, wherein the at least one receiver comprises: a radio frequency detector having at least one input configured to receive a detector input signal derived from the received signal received by the antenna structure, wherein a receive signal chain provides a receive signal path from the antenna structure to the detector for a receive signal based on the received signal received by the antenna structure; at least one low-noise amplifier provided in the receive signal chain and configured to amplify a low-noise amplifier input signal derived from the received signal received by the antenna structure, the low-noise amplifier producing a low-noise amplifier output signal, which is provided to the receive signal chain such that the detector input signal can be derived from the low-noise amplifier output signal; and at least one high-pass filter provided in the receive signal path between the low-noise amplifier and the antenna structure such that the receive signal path in the receive signal chain can be routed through the high-pass filter, the high-pass filter being configured to filter undesirable frequencies out of the receive signal in the receive signal path traveling from the antenna structure to the low-noise amplifier, wherein the low-pass filter is an absorptive filter that squelches the undesirable frequencies.

Some embodiments disclosed herein are designed to detect targets-of-interest that contain nonlinear junctions. Preferably, the apparatus for detecting target devices is mobile and may be man-portable or carried onboard a vehicle. Examples of suitable vehicles include, without limitation, manned or unmanned aerial, land, or marine vehicles. In some examples, the vehicle itself may be operated by a single user or operator in a relevant operational environment.

Some embodiments disclosed herein are directed to a high-dynamic-range radio-frequency transceiver that allows its user to detect nonlinear junctions using four different modes—of operation.

In some embodiments disclosed herein, the transceiver incorporates four similar (but still distinctly different) types of detectors that operate in linear, harmonic, intermodulation, and cross-modulation modes, respectively. Some embodiments disclosed herein combine the four modes into a unified architecture that allows its user to reconfigure it to detect a wide variety of targets and improve the probability of detecting any one particular target.

In some embodiments disclosed herein, the user may select between the four aforementioned modes of detection. Some embodiments disclosed herein, when operating in the harmonic mode or the cross-modulation mode, switch between banks of harmonically-related filters to stitch together a wideband nonlinear target response. In some embodiments disclosed herein, diplexers are implemented as absorptive filters to minimize system-generated harmonics. In some embodiments disclosed herein that are capable of operating in the cross-modulation mode, separate transmitters are implemented to minimize system-generated distortion.

The embodiments disclosed herein are capable of being incorporated in radars, which not only detect but also determine the range to the targets-of-interest.

Potential uses for the embodiments disclosed herein include, without limitation, finding weapons and ordnance, tracking moving manmade objects, tracking tags that are placed on moving objects, locating enemy radios and phones, and performing counter-surveillance.

Potential commercial uses for the embodiments disclosed herein include, without limitation, tracking insects and animals, locating people during emergencies, locating devices whose electromagnetic emissions exceed legal limits, avoiding automobile collisions, and monitoring vital signs.

These and other aspects of the embodiments herein will be better appreciated and understood when considered in conjunction with the following description and the accompanying drawings. It should be understood, however, that the following descriptions, while indicating exemplary embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 is a schematic diagram illustrating a simplified depiction of a basic principle underlying the embodiments disclosed herein;

FIG. 2A is a schematic diagram illustrating the linear mode of operation according to some of the embodiments disclosed herein;

FIG. 2B is a schematic diagram illustrating the harmonic mode of operation according to some of the embodiments disclosed herein;

FIG. 3A is a schematic diagram illustrating a simplified depiction of a transmitter showing the basic components of a transmitter according to some of the embodiments disclosed herein;

FIG. 3B is a schematic diagram illustrating a simplified depiction of a receiver showing the basic components of a receiver according to some of the embodiments disclosed herein;

FIG. 4A is a schematic diagram illustrating a transmitter that employs an absorptive filter according to some of the embodiments disclosed herein;

FIG. 4B is a schematic diagram illustrating a receiver that employs an absorptive filter according to some of the embodiments disclosed herein;

FIG. 5 is a graph showing the relationship between the passed and rejected frequencies of the filters in the receiver and the passed and rejected frequencies of the filters in the transmitter according to some of the embodiments disclosed herein;

FIG. 6 is a schematic diagram illustrating a transmitter that employs a pre-amplifier and a power amplifier along with low-pass filtering for each amplifier stage according to some of the embodiments disclosed herein;

FIG. 7 is a schematic diagram illustrating a receiver that employs a plurality of low-noise amplifiers in series along with high-pass filtering for each amplifier stage according to some of the embodiments disclosed herein;

FIG. 8 is a schematic diagram illustrating a receiver that employs a limiter placed before each amplifier stage and an attenuator placed after each amplifier stage according to some of the embodiments disclosed herein;

FIG. 9 is a schematic diagram illustrating a transmitter that employs a feed-forward filter reflection (FFFR) device between a power amplifier stage and the transmitting antenna according to some of the embodiments disclosed herein;

FIGS. 10A and 10B show graphs illustrating the frequency response of the high-pass and low-pass filters for additional operating frequency bands of target detection apparatuses according to some of the embodiments disclosed herein;

FIG. 11 is a schematic diagram illustrating a transmitter that employs a pre-amplifier and a power amplifier along with banks of low-pass filters for each amplifier stage and for the transmitting antenna with each of the bank of low-pass filters for the power amplifier being of the absorptive type according to some of the embodiments disclosed herein;

FIG. 12 is a schematic diagram illustrating a receiver that employs a limiter placed before each amplifier stage and an attenuator placed after each amplifier stage and having a bank of high-pass filters provided at a location after the receiving antenna according to some of the embodiments disclosed herein;

FIG. 13A is a schematic diagram illustrating the intermodulation mode of operation according to some of the embodiments disclosed herein;

FIG. 13B is a schematic diagram illustrating the cross-modulation mode of operation according to some of the embodiments disclosed herein;

FIG. 14 is a schematic diagram illustrating a reconfigurable transceiver according to some of the embodiments disclosed herein;

FIG. 15 is a schematic diagram illustrating a reconfigurable transceiver configured in the linear mode according to some of the embodiments disclosed herein;

FIG. 16 is a schematic diagram illustrating a reconfigurable transceiver configured in the harmonic mode according to some of the embodiments disclosed herein;

FIG. 17 is a schematic diagram illustrating a reconfigurable transceiver configured in the intermodulation mode according to some of the embodiments disclosed herein; and

FIG. 18 is a schematic diagram illustrating a reconfigurable transceiver configured in the cross-modulation mode according to some of the embodiments disclosed herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

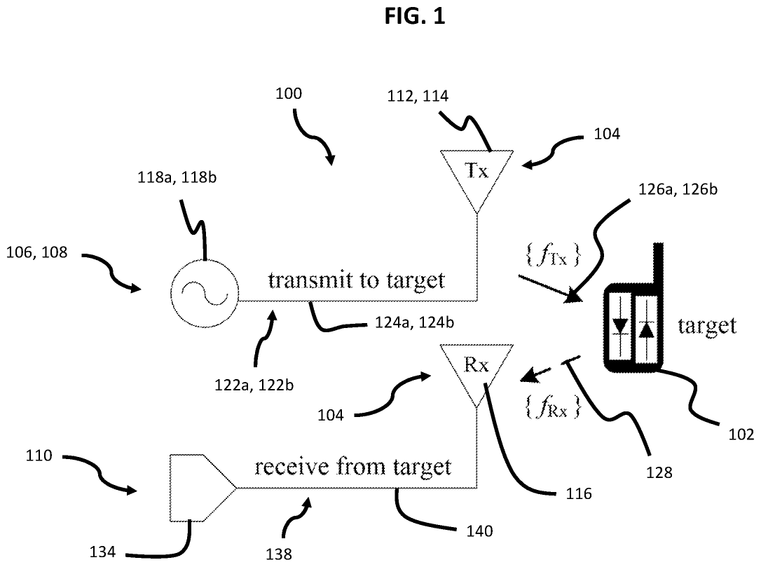

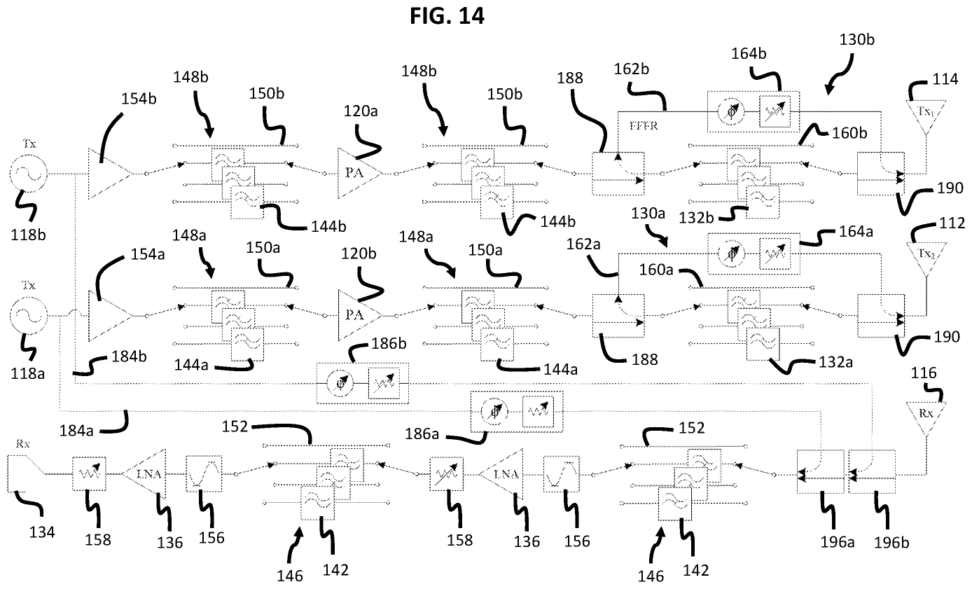

Referring to FIGS. 1 through 18, the embodiments disclosed herein are directed to apparatuses for detection of one or more target objects. Referring to FIGS. 14-18, the embodiments disclosed herein in an apparatus 100 for detection of one or more target objects 102. The apparatus 100 includes an antenna structure 104, at least one transmitter 106 or 108, and at least one receiver 110. Transmitter and receiver as used herein exclude the antenna structure. The word transceiver is sometimes used herein to refer to the combination of at least one transmitter, at least one receiver, and the associated appropriate antenna structure. The terms antenna structure as used herein encompasses an antenna or an antenna array used to both transmit and receive, one or more antennas or antenna arrays used to transmit in combination with one or more antennas or antenna arrays used to receive, and any combination thereof. In the illustrated examples herein, each transmitter 106 and 108 is provided with a dedicated transmitting antenna 112 and 114, respectively, and the receiver 110 is provided with a dedicated receiving antenna 116.

The at least one transmitter 106 or 108 communicates electrically with the antenna structure 104, and is configured to generate a transmitted signal 126a and 126b, respectively, that is transmitted by the antenna structure 104. The at least one receiver 110 communicates electrically with the antenna structure 104, and is configured to receive a received signal emanating from the one or more target objects 102 in response to the transmitted signal 126a, 126b and is received by the antenna structure 104. In the illustrated example, the received signal 128 is received by the receiving antenna 116 and outputted to the circuitry within the receiver 110, which form the receive signal chain 138 and the receive signal path 140, as the receive signal.

The apparatus 100 operates in one of four user-selectable automatically-selectable modes of operation selected from the group consisting of linear mode, harmonic mode, intermodulation mode, and cross-modulation mode. The apparatus 100 is configured to be switchable from one of these modes to another of these modes by a user or by automatic control.

Each of the transmitters 106 and 108 includes a radio frequency source 118a and 118b, respectively, and a power amplifier 120a and 120b, respectively. The radio frequency source 118a, 118b is configured to output a radio frequency source output signal to a transmit signal chain 122a and 122b, respectively, that begins with the radio frequency source and ends with the antenna structure. The transmit signal chain 122a, 122b provides a transmit signal path 124a and 124b, respectively, from the radio frequency source 118a, 118b to the antenna structure 104 for a transmit signal. The transmit signal chain 122a, 122b provides for signal communication between the radio frequency source 118a, 118b and the antenna structure 104. The source output signal, outputted by the radio frequency source 118a, 118b, is amplified with a gain needed to generate an antenna input transmit signal that is provided to the antenna structure 104. The power amplifier 120a, 120b is provided in the transmit signal chain 122a, 122b and is configured to amplify the source output signal to provide at least a portion of the gain needed to generate the antenna input transmit signal that is provided to the antenna structure 104 to thereby generate the transmitted signal 126a, 126b. In some of the drawing figures that illustrate modes where only one transmitter is used, the transmitted signal may be designated {f_{Tx}}. The power amplifiers 120a, 120b may be identical, but they need not be identical in some applications. Each power amplifier 120a, 120b has an input signal and an output signal.

The receiver 110 includes a radio frequency detector 134 and at least one low-noise amplifier 136. The radio frequency detector 134 has at least one input configured to receive a detector input signal derived from the received signal 128 received by the antenna structure 104. A receive signal chain 138 provides a receive signal path 140 from the antenna structure 104 to the detector 134 for a receive signal that is derived from the received signal 128 and that goes through processing along the receive signal path 140.

The low-noise amplifier 136 is provided in the receive signal chain 138 and is configured to amplify a low-noise amplifier input signal derived from the received signal 128 received by the antenna structure 104. The low-noise amplifier produces a low-noise amplifier output signal, which is provided to the receive signal chain 138 such that the detector input signal, which the input signal to the detector 134, can be derived from the low-noise amplifier output signal. The receive signal chain 138 may include a plurality of low-noise amplifiers 136 connected in series between the detector 134 and the antenna structure 104, as further described below in greater detail, in order to provide the necessary gain to utilize enough of the time-domain amplitude detection range of the detector 134 to obtain a sufficiently detailed representation of the received signal 128 to allow analysis of the frequency spectrum of the received signal 128 if needed for, for example, target object identification by comparison of the frequency spectrum of the received signal 128 with known target device frequency signatures. The plurality of low-noise amplifiers 136 may be identical, but they need not all be identical. The plurality of low-noise amplifiers 136 may each have different characteristics such as, for example, different gains or different impedances.

In some examples, the receiver 110 may further include at least one high-pass filter 142. The at least one high-pass filter 142 is provided such that the receive signal path 140 in the receive signal chain 138 can be selectively routed through the high-pass filter 142. The high-pass filter 142 is configured to filter the low-noise amplifier input signal derived from the received signal 128 received by the antenna structure 104. A plurality of high-pass filters 142 may be provided in the receive signal chain 138 with one high-pass filter 142 filtering the receive signal before the receive signal is inputted to a corresponding one of a plurality of low-noise amplifiers 136 provided in the receive signal chain 138.

In some examples, the receiver 110 may further include at least one bank 146 of high-pass filters 142. The bank 146 of high-pass filters 142 includes a plurality of high-pass filters 142 provided in parallel such that the receive signal path in the receive signal chain can be selectively routed through a selected one of the plurality of high-pass filters 142. Each of the plurality of high-pass filters 142 provided in a bank 146 of such filters is configured to filter the low-noise amplifier input signal derived from the received signal 128 received by the antenna structure 104 when it is selected such that the receive signal path 140 is routed through it. Each of the plurality of high-pass filters 142, in a bank 146 of high pass filters, is configured to filter the receive signal in the receive signal path 140 at a location between a low-noise amplifier 136 and the antenna structure 104 when it is selected such that the receive signal path 140 is routed through it.

The power amplifier 120a, 120b has an input signal and an output signal. In some examples, the transmitter 106, 108 may further include at least one low-pass filter 144a, 144b, respectively. The low-pass filter 144a, 144b is provided such that the transmit signal path 124a, 124b in the transmit signal chain 122a, 122b can be selectively routed through the low-pass filter 144a, 144b. The low-pass filter 144a, 144b is configured to filter the power amplifier output signal derived from the source output signal outputted by the radio frequency source 118a, 118b. In some examples, a plurality of low-pass filters 144a, 144b may be provided in the transmit signal chain 122a, 122b with one low-pass filter 144a, 144b filtering the transmit signal after the transmit signal is outputted from a corresponding one of a plurality of power amplifiers 120a, 120b provided in the transmit signal chain 122a, 122b.

In some examples, the transmitter 106, 108 may further include at least one bank 148a, 148b, respectively, of low-pass filters 144a, 144b. The bank 148a, 148b of low-pass filters 144a, 144b includes a plurality of the low-pass filters provided in parallel such that the transmit signal path 124a, 124b in the transmit signal chain 122a, 122b can be selectively routed through a selected one of the plurality of low-pass filters 144a, 144b. Each of the plurality of low-pass filters 144a, 144b is configured to filter the power amplifier output signal derived from the source output signal outputted by the radio frequency source 118a, 118b when the transmit signal path 124a, 124b is routed through the selected one of the plurality of low-pass filters 144a, 144b. Each of the plurality of low-pass filters 144a, 144b, in a bank 148a, 148b of low-pass filters, is configured to filter the transmit signal in the transmit signal path 124a, 124b at a location between a power amplifier 120a, 120b, or a pre-amplifier 154a, 154b, and the antenna structure 104 when it is selected such that the transmit signal path 124a, 124b is routed through it.

In some examples, each of the plurality of low-pass filters 144a, 144b in a bank 148a, 148b of low-pass filters corresponds to a corresponding one of the plurality of high-pass filters 142 in a bank 146 of high-pass filters. Each of the plurality of high-pass filters in a bank 146 corresponds to a corresponding one of the plurality of low-pass filters in a bank 148a, 148b, such that each of the plurality of high-pass filters in a bank 146 and the corresponding one of the plurality of low-pass filters in a bank 148a, 148b form a pair of corresponding high-pass and low-pass filters. Each of the plurality of low-pass filters in a bank 148a, 148b passes frequencies in a corresponding transmit band of a plurality of transmit bands. Each of the plurality of high-pass filters in a bank 146 effectively rejects frequencies in the corresponding transmit band, of the plurality of transmit bands, corresponding to the corresponding one of the plurality of low-pass filters in a bank 148a, 148b such that the frequency of the transmitted signal that is transmitted by the antenna structure 104 can be scanned over the plurality of transmit bands by switching from one pair of corresponding high-pass and low-pass filters corresponding to one of the plurality of transmit bands to another pair of corresponding high-pass and low-pass filters corresponding to another one of the plurality of transmit bands.

In the illustrated example, each bank 148a, 148b of low-pass filters further includes a transmit signal bypass path 150a, 150b, respectively, to allow the plurality of low-pass filters 144a, 144b in each bank 148a, 148b to be selectively bypassed by the transmit signal path 124a, 124b by selectively routing the transmit signal through the transmit signal bypass path 150a, 150b. Each bank 146 of high-pass filters 142 further includes a receive signal bypass path 152 to allow the plurality of high-pass filters 142 to be selectively bypassed by the receive signal path 140 by selectively routing the receive signal through the receive signal bypass path 152. Bypassing the plurality of high-pass and low-pass filters in the banks of filters may be necessary for operating the apparatus 100 in some modes such as, for example, the linear mode as further discussed herein below.

In the illustrated example, the transmitter 106, 108 may further include a plurality of transmit chain amplifiers connected in series in the transmit signal chain 122a, 122b. Each of the plurality of transmit chain amplifiers has an input for receiving a transmit chain amplifier input signal and an output for outputting a transmit chain amplifier output signal. Each of the plurality of transmit chain amplifiers has a gain. The plurality of transmit chain amplifiers includes a first transmit chain amplifier and a last transmit chain amplifier. The first transmit chain amplifier receives the source output signal at its input, and the last transmit chain amplifier has its transmit chain amplifier output signal routed to the antenna structure 104. The transmit chain amplifier input signal of each of the plurality of transmit chain amplifiers is derived from the transmit chain amplifier output of a preceding one of the plurality of transmit chain amplifiers except for the first transmit chain amplifier. The first transmit chain amplifier is a pre-amplifier 154a, 154b, and the power amplifier 120a, 120b is the last transmit chain amplifier. Additional power amplifiers 120a, 120b may be provided in series between the pre-amplifier 154a, 154b and the power amplifier 120a, 120b as needed. The plurality of transmit chain amplifiers provide the gain needed to generate the antenna input transmit signal that is provided to the antenna structure 104 to thereby generate the transmitted signal 126a, 126b.

In the illustrated embodiment, the receiver 110 may further include a plurality of receive chain amplifiers connected in series in the receive signal chain 138. Each of the plurality of receive chain amplifiers has an input for receiving a receive chain amplifier input signal, and an output for outputting a receive chain amplifier output signal. Each of the plurality of receive chain amplifiers has a gain. The plurality of receive chain amplifiers includes a first receive chain amplifier and a last receive chain amplifier. The receive chain amplifier input signal of the first receive chain amplifier is derived from the received signal 128 received by the antenna structure 104. The last receive chain amplifier has its receive chain amplifier output signal routed to the radio frequency detector 134. The receive chain amplifier input signal of each of the plurality of receive chain amplifiers is derived from the receive chain amplifier output of a preceding one of the plurality of receive chain amplifiers, except for the first receive chain amplifier. The first receive chain amplifier may be the low-noise amplifier 136. For example, the plurality of receive chain amplifiers may all be of the same type as low-noise amplifier 136. The plurality of receive chain amplifiers provide the gain needed to amplify the received signal 128 received by the antenna structure 104 such that the radio frequency detector can detect the received signal 128.

In the illustrated embodiment, the transmitter 106, 108 may include a plurality of banks 148a, 148b, respectively, of low-pass filters 144a, 144b. Each bank 148a, 148b of low-pass filters is configured to selectively filter the transmit chain amplifier output signal of a corresponding one of the plurality of transmit chain amplifiers 154a, 154b, 120a, 120b. Each bank 148a, 148b of low-pass filters is provided in the transmit chain between the output of the corresponding one of the plurality of transmit chain amplifiers 154a, 154b, 120a, 120b and the input of the succeeding one of the plurality of transmit chain amplifiers, except for the last transmit chain amplifier. The corresponding bank 148a, 148b of low-pass filters corresponding to the last transmit chain amplifier 120a, 120b is provided between the output of the last transmit chain amplifier 120a, 120b and the antenna structure 104.

In the illustrated embodiment, the receiver 110 includes a plurality of banks 146 of high-pass filters 142. Each bank 146 of high-pass filters 142 is configured to selectively filter the receive chain amplifier input signal of a corresponding one of the plurality of receive chain amplifiers 136. Each bank 146 of high-pass filters 142 is provided in the receive chain between the input of the corresponding one of the plurality of receive chain amplifiers 136 and the output of the preceding one of the plurality of receive chain amplifiers 136, except for the first receive chain amplifier 136. The first receive chain amplifier 136 has its corresponding bank 146 of high-pass filters 142 provided between the input of the first receive chain amplifier 136 and the antenna structure 104. In the illustrated embodiment, all the plurality of receive chain amplifiers may be low-noise amplifiers 136.

In the illustrated embodiment, the receiver 110 further includes a plurality of limiters 156 and a plurality of attenuators 158. A corresponding limiter 156 is provided before the input of each of the plurality of receive chain amplifiers 136, in the direction from the antenna structure 104 to the radio frequency detector 134 in the receive chain 138, to prevent saturation of each of the plurality of receive chain amplifiers 136. A corresponding attenuator 158 is placed after the output of each of the plurality of receive chain amplifiers 136, in the direction from the antenna structure 104 to the radio frequency detector 134 in the receive chain 138, to maximize the available range of voltages to be detected by the radio frequency detector 134.

In the illustrated embodiment, the transmitter 106, 108 further includes a feed-forward filter reflection device 130a, 130b, respectively. The feed-forward filter reflection device 130a, 130b is provided in the transmit chain 122a, 122b to further diminish the significance of undesirable frequencies in the antenna input transmit signal that is provided to the antenna structure 104. The feed-forward filter reflection device 130a, 130b is provided in the transmit chain 122a, 122b between the bank 148a, 148b of low-pass filters corresponding to the last transmit chain amplifier, which is provided after the output of the last transmit chain amplifier 120a, 120b, and the antenna structure 104.

The bank 148a, 148b of low-pass filters 144a, 144b corresponding to the last transmit chain amplifier 120a, 120b has an input and an output. The feed-forward filter reflection device 130a, 130b includes at least one bank of low-pass filters 132a, 132b, a transmit signal bypass path 160a, 160b, and a feed-forward path 162a, 162b.

The bank of low-pass filters 132a, 132b includes a plurality of low-pass filters 132a, 132b arranged in parallel provided such that the transmit signal path 124a, 124b in the transmit signal chain can be selectively routed through a selected one of the plurality of low-pass filters 132a, 132b. Each of the plurality of low-pass filters 132a, 132b is configured to filter the transmit signal from the output of the bank 148a, 148b of low-pass filters 144a, 144b corresponding to the last transmit chain amplifier 120a, 120b when it is selected such that the transmit signal path is routed through it. The transmit signal from the output of the bank 148a, 148b of low-pass filters 144a, 144b corresponding to the last transmit chain amplifier 120a, 120b is derived from the source output signal.

The transmit signal bypass path 160a, 160b allows the plurality of low-pass filters 132a, 132b of the feed-forward filter reflection device 130a, 130b to be selectively bypassed by the transmit signal path 124a, 124b by selectively routing the transmit signal through the transmit signal bypass path 160a, 160b of the feed-forward filter reflection device 130a, 130b.

The feed-forward path 162a, 162b routes a signal reflected by the bank of low-pass filters 132a, 132b of the feed-forward filter reflection device, which contains the undesirable frequencies, around the bank of low-pass filters 132a, 132b of the feed-forward filter reflection device such that the signal reflected by the bank of low-pass filters 132a, 132b of the feed-forward filter reflection device rejoins the transmit signal path 124a, 124b from the output of the bank of low-pass filters 132a, 132b of the feed-forward filter reflection device for destructive interference with the undesirable frequencies in the transmit signal from the output of the bank of low-pass filters 132a, 132b of the feed-forward filter reflection device before the transmit signal path reaches the transmit signal input of the antenna structure 104.

In the illustrated embodiment, the feed-forward path 162a, 162b is provided with a tuner 164a, 164b for tuning the feed-forward filter reflection device to enhance the destructive interference between the undesirable frequencies in the signal reflected by the bank of low-pass filters 132a, 132b of the feed-forward filter reflection device and the undesirable frequencies in the transmit signal from the output of the bank of low-pass filters 132a, 132b of the feed-forward filter reflection device 130a, 130b. The signal reflected by the bank of low-pass filters 132a, 132b of the feed-forward filter reflection device refers to the signal reflected by any one of the low-pass filters 132a, 132b of the feed-forward filter reflection device that is engaged to be part of the transmit signal path 124a, 124b.

In some embodiments disclosed herein, the transmitter 106, 108 may include at least one low-pass filter 144a, 144b provided in the transmit signal path 124a, 124b between the power amplifier 120a, 120b and the antenna structure 104, or between a preamplifier or power amplifier and the succeeding power amplifier, that is an absorptive filter that squelches the undesirable frequencies. As with the reflective type low-pass filters 144a, 144b, absorptive type low pass filters can be used as low-pass filters 144a, 144b and can be provided in the transmit signal path 124a, 124b between the pre-amplifier 154a, 154b or the power amplifier 120a, 120b and the antenna structure 104 or a succeeding power amplifier 120a, 120b such that the transmit signal path 124a, 124b in the transmit signal chain 122a, 122b can be routed through the absorptive low-pass filter 144a, 144b. As with the other type of low-pass filters 144a, 144b, the absorptive low-pass filter 144a, 144b is configured to filter undesirable frequencies out of the transmit signal in the transmit signal path 124a, 124b traveling to the antenna structure 104.

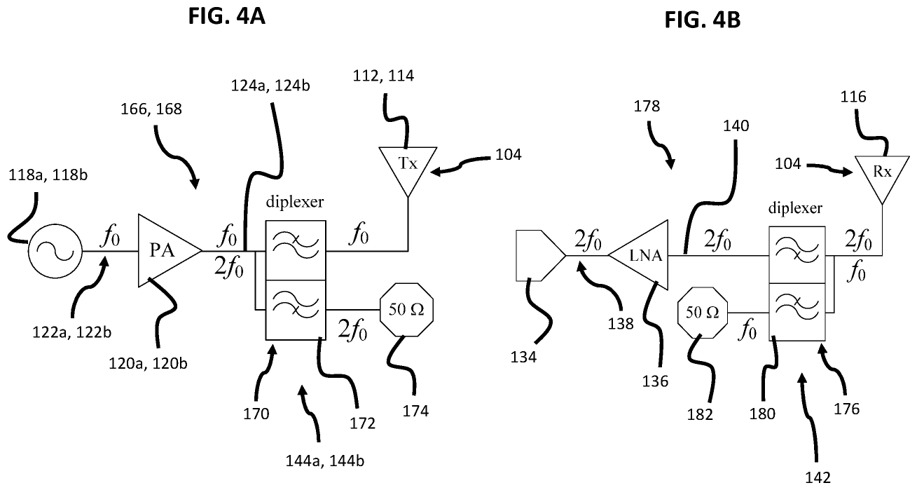

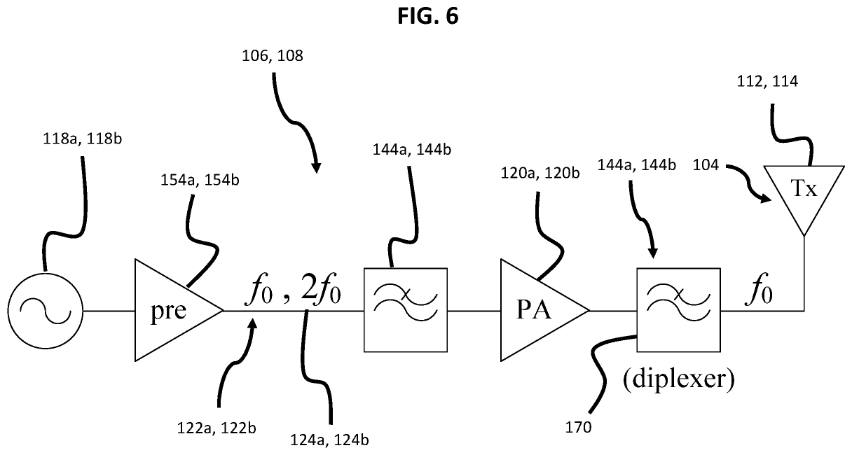

FIGS. 4A and 6 illustrate transmitters 166 and 168 in accordance with the embodiments disclosed herein that employ an absorptive low-pass filter 170, which can be used as the absorptive low-pass filters 144a, 144b. FIGS. 4A and 6 provide a more detailed illustration of an absorptive low-pass filter 170. The absorptive low-pass filter 170 includes a diplexer 172 that has a signal input, a low-pass output, and a high-pass output. The signal input of the diplexer 172 receives the output of the power amplifier 120a, 120b. The low-pass output of the diplexer 172 is connected to the transmit signal path such that the low-pass output of the diplexer 172 is directed toward the transmitting antenna 112, 114 or the antenna structure 104 as the case may be. The high-pass output of the diplexer 172 is connected to a load 174 (e.g. 50Ω matched load) such that any undesired frequencies are absorbed in the load rather than be reflected back within the transmitter.

Similarly, in some examples, absorptive high-pass filters 176 as illustrated in FIG. 4B may be utilized as the high-pass filters 142 in the receiver 110. Accordingly, the high-pass filters 142 can be absorptive high-pass filters 176 that squelch the undesirable frequencies in the receiver 110. An absorptive high-pass filter 176 would take the place of the high-pass filters 142 in the receiver 110 as a direct replacement. Accordingly, in the receiver 110, the absorptive high-pass filter 176 is provided in the receive signal path 140 between the low-noise amplifier 136 and the antenna structure 104 or a preceding low-noise amplifier 136 such that the receive signal path 140 in the receive signal chain 138 can be routed through the absorptive high-pass filter 176. The absorptive high-pass filter 176 is configured to filter undesirable frequencies out of the receive signal in the receive signal path 140 traveling from the antenna structure 104 or a preceding low-noise amplifier 136 to a low-noise amplifier 136.

FIG. 4B illustrates a receiver 178 in accordance with the embodiments disclosed herein that employ an absorptive high-pass filter 176, which can be used as the high-pass filters 142. FIG. 4B provides a more detailed illustration of an absorptive high-pass filter 176. The absorptive high-pass filter 176 includes a diplexer 180 that has a signal input, a low-pass output, and a high-pass output. The signal input of the diplexer 180 receives the output of a low-noise amplifier 136 or the receive signal derived from the received signal received by, for example, the receiving antenna 116 or the antenna structure 104. The high-pass output of the diplexer 180 is connected to the receive signal path 140 such that the high-pass output of the diplexer 180 is directed toward the detector 134. The low-pass output of the diplexer 180 is connected to a load 182 (e.g. 50 (matched load) such that any undesired frequencies are absorbed in the load and are not re-reflect within the receiver to potentially generate additional harmonics.

In the illustrated embodiment of FIGS. 14-18, the apparatus 100 further includes an intermodulation signal path 184a, 184b to allow the operation of the apparatus 100 in the intermodulation mode. The intermodulation signal path 184a, 184b is configured to selectively connect the output signal of the radio frequency source 118a, 118b of the transmitter 106, 108 to the receive signal path 140 of the receiver 110 between the antenna structure 104 and the first low-noise amplifier 136. The intermodulation signal path 184a, 184b is configured to allow the use of the radio frequency source output signal for cancellation of undesirable frequencies in the receive signal in the receive signal path 140 traveling from the antenna structure 104 to the first low-noise amplifier. A tuner 186a, 186b is provided in the intermodulation signal path 184a, 184b to maximize the elimination of undesirable frequencies through destructive interference between the undesirable frequencies in the receive signal and the output signal of the radio frequency source 118a, 118b.

In the illustrated embodiment of FIGS. 14-18, the apparatus 100 includes a plurality of transmitters 106 and 108. Each of the plurality of transmitters 106, 108 has a radio frequency source output signal that is of a different frequency compared to other transmitters of the plurality of transmitters. Each of the plurality of transmitters 106, 108 has the same categories of components (e.g. signal sources, amplifiers, filters, etc.) and the same transmit chain layout and the same layout for its intermodulation signal path 184a, 184b. Furthermore, each of the plurality of transmitters has the same transmit signal path layout for its transmit signal path 124a, 124b.

The apparatus 100 includes a plurality of transmitters 106, 108 communicating with the antenna structure 104. Each of the plurality of transmitters 106, 108 is configured to generate a transmitted signal that is transmitted by the antenna structure 104 such that a plurality of transmitted signals 126a and 126b are transmitted by the antenna structure 104. The apparatus 100 further includes at least one receiver 110 communicating with the antenna structure 104. The receiver 110 is configured to receive a received signal that emanates from the one or more target objects in response to the plurality of transmitted signals and that is received by the antenna structure 104. The plurality of transmitters providing for a plurality of transmitted signals give the apparatus 100 the capability of operating in a cross-modulation mode.

Each of the plurality of transmitters 106, 108 includes a radio frequency source 118a, 118b and at least one power amplifier 120a, 120b. The radio frequency source 118a, 118b is configured to output a radio frequency source output signal to a transmit signal chain 122a, 122b that begins with the radio frequency source 118a, 118b and ends with the antenna structure 104. The transmit signal chain 122a, 122b provides a transmit signal path 124a, 124b from the radio frequency source 118a, 118b to the antenna structure 104 for a transmit signal. The transmit signal chain 122a, 122b provides for signal communication between the radio frequency source 118a, 118b and the antenna structure 104. The source output signal is amplified with a gain needed to generate an antenna input transmit signal that is provided to the antenna structure 104.

The power amplifier 120a, 120b is provided in the transmit signal chain 122a, 122b and configured to amplify the source output signal to provide at least a portion of the gain needed to generate the antenna input transmit signal that is provided to the antenna structure 104 to thereby generate a corresponding one of the plurality of transmitted signals 126a, 126b. Each of the plurality of transmitters 106, 108 has a radio frequency source output signal that is of a different frequency compared to other transmitters of the plurality of transmitters 106, 108 such that each of the plurality of transmitted signals 126a, 126b has a frequency that is different from other transmitted signals of the plurality of transmitted signals 126a, 126b. The frequency of each of the plurality of transmitted signals 126a, 126b corresponds to the radio frequency source output signal frequency of a corresponding one of the plurality of transmitters 106, 108.

In the illustrated embodiments, the antenna structure 104 includes a plurality of transmitter antennas 112, 114 and a receiver antenna 116. Each of the plurality of transmitter antennas 112, 114 is energized by a corresponding one of the plurality of transmitters 106, 108 to transmit a corresponding one of the plurality of transmitted signals 126a, 126b. The receiver antenna 116 communicates with the receive signal chain and provides an antenna output receive signal to the receive signal path 140 of the receiver 110 based on the received signal received by the receiver antenna 116.

In the embodiments of FIGS. 4A and 6 herein, at least one low-pass filter 170 is provided in the transmit signal path 124a, 124b between a power amplifier 120a, 120b and the antenna structure 104 such that the transmit signal path 124a, 124b in the transmit signal chain 122a, 122b can be routed through the low-pass filter 170. The low-pass filter 170 is configured to filter undesirable frequencies out of the transmit signal in the transmit signal path 124a, 124b traveling to the antenna structure 104. In these embodiments, the low-pass filter 170 is an absorptive filter that squelches the undesirable frequencies.

In the embodiment of FIG. 4B, at least one high-pass filter 176 is provided in the receive signal path 140 between a low-noise amplifier 136 and the antenna structure 104 such that the receive signal path 140 in the receive signal chain 138 can be routed through the high-pass filter 176. The high-pass filter 176 is configured to filter undesirable frequencies out of the receive signal in the receive signal path 140 traveling from the antenna structure 104 to a low-noise amplifier 136. In this embodiment, the low-pass filter 176 is an absorptive filter that squelches the undesirable frequencies.

The detectors 134 may, for example, be formed by an analog-to-digital converter (ADC) communicating with a computer system running appropriate signal processing software. The radio frequency sources 118a, 118b may, for example, be signal generators that can selectively generate signals over a relatively wide frequency range that is wide enough to range over all the desired transmit bands. Any combination or permutation of the disclosed features is considered to be part of the disclosed embodiments. The word “effectively” as used herein means to such a degree as to be sufficient for achieving the intended result. Vector modulators are non limiting examples of devices that can be used for the tuners in the various disclosed embodiments. The receive signal as used herein refers to the signal carried at any given location and at any given time in the receive signal path 140 in the receiver 110. The transmit signal as used herein refers to the signal carried at any given location and at any given time in the transmit signal path 124a, 124b in the transmitter 106, 108. The transmitted signal or signals and the received signal refer to the signals travelling through the air from and to the antenna or antenna structure.

The transmit signal chain as used herein refers to the chain of components such as, for example, radio frequency sources, amplifiers, filters, switches, couplers, connecting conductors, and antennas or antenna structures that cooperatively provide the transmit signal path from the radio frequency sources to the antennas or antenna structures when the transmit signal chain is in active operation. The receive signal chain as used herein refers to the chain of components such as, for example, radio frequency detectors, amplifiers, filters, switches, couplers, connecting conductors, and antennas or antenna structures that cooperatively provide the receive signal path from the antennas or antenna structures to the radio frequency detectors when the receive signal chain is in active operation. The transmit signal path as used herein refers to the signal conduction pathway permitting signal communication between the radio frequency sources and the antennas or antenna structures provided by the transmit signal chain when the transmit signal chain is in active operation. The receive signal path as used herein refers to the signal conduction pathway permitting signal communication between the antennas or antenna structures and the radio frequency detectors provided by the receive signal chain when the receive signal chain is in active operation. The components listed above are not all required to define a transmit or receive signal chain. For any signal chain appearing in any of claims, only components positively recited in the claim are required to define the chain, although such a claim would read on apparatus including components in addition to those required by the claim. Furthermore, the lists of components above should not be construed as exhaustive or limiting.

In the drawings, components having identical numerical portions in their drawing reference labels may be identical, but they need not be identical. They may be generally similar or be of a similar type or function, but they may have differences in their exact specifications. Further elaboration on the operation of the apparatus 100 is provided in the following discussion.

The embodiments herein relate to a radio-frequency transceiver (100) which allows its user to perform detection of targets (102) containing nonlinear junctions, using four different modes-of-operation. Switching between the four modes (and the filter bands within two of these modes) enables measurement of the responses of targets-of-interest for many different configurations of the radar. Across all modes, the transceiver architecture establishes a high dynamic range, transmitting at least 10 mW of highly-linear probe power to the target and receiving as little as 200 fW of power reflected from the target.

The concept of nonlinear junction detection is illustrated in FIG. 1. In the example of FIG. 1, the target (102) contains semiconductor-based components such as diodes. The system's transmit (Tx) chain (122a, 122b) is shown in the upper part of the figure, while the receive (Rx) chain (138) is shown in the lower part of the figure. The system transmits to the target (102) a set of known frequencies {f_{Tx}}. Some of this transmission couples into the target (102) through its antenna. The electromagnetically-nonlinear (e.g. semiconductor junction) properties of the front-end circuit of the target distort the transmission and generate new frequencies. Those frequencies re-radiated by the target antenna make up {f_{Rx}}, a set that contains {f_{Tx}} as well as those new frequencies generated by the target. The spectrally broad {f_{Rx}} is captured by the receiver (110). As most (naturally-occurring) clutter items are electromagnetically linear, reception of frequencies in {f_{Rx}} that were not part of {f_{Tx}} indicates the presence of (man-made) nonlinear junctions.

If the system performs detection only (without providing range-to-target), then the transceiver 100 is called a “nonlinear junction detector” (NLJD). Some embodiments herein are directed to a NLJD that is reconfigurable between frequency bands and switchable between linear, harmonic, intermodulation, and cross-modulation modes.

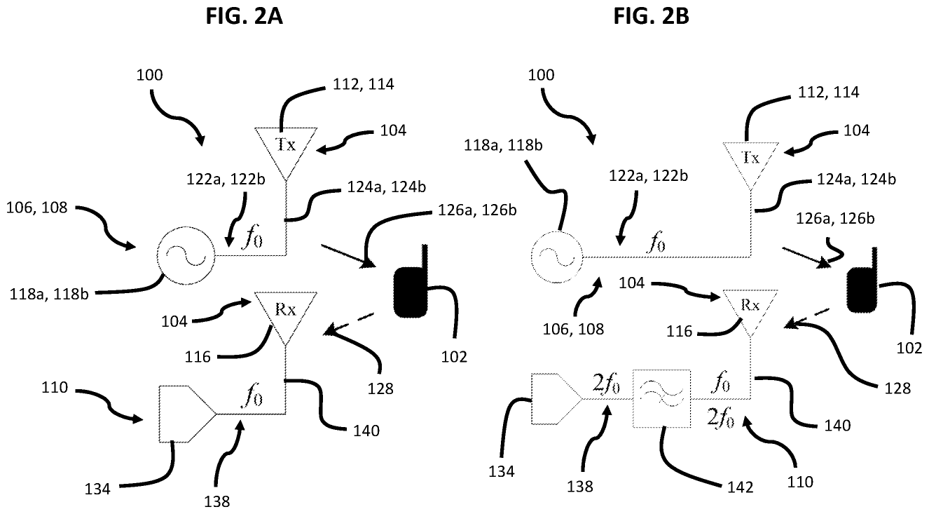

If the system is configured in a (traditional) linear mode-of-operation, then at any particular moment it will transmit the instantaneous frequency f₀ and it will receive that same frequency f₀. This scenario, i.e. the linear mode, is illustrated in FIG. 2A. If the system is configured in a harmonic mode, then it will transmit f₀ but it will receive multiples of f₀ such as 2 f₀, 3 f₀, 4 f₀, and so on. The harmonic scenario is illustrated in FIG. 2B. Without loss of generality, only the harmonic 2 f₀ is shown in the drawing figure.

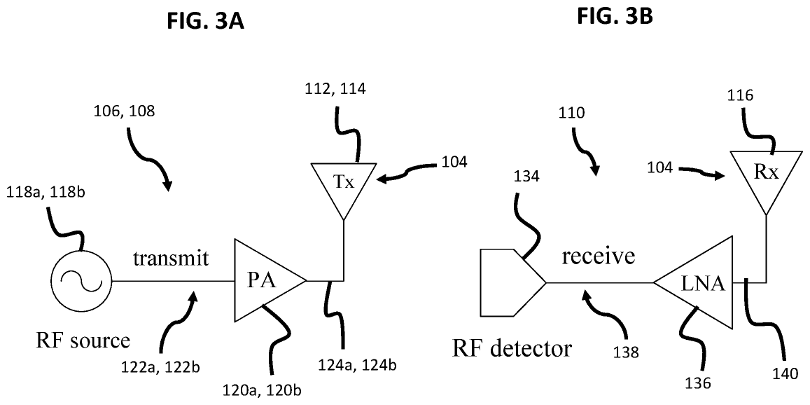

The harmonic mode exploits the nonlinear properties of the target. The system 100 has demonstrated moving-target-indication and synthetic-aperture imaging in the harmonic mode, which is one of the operating modes of the reconfigurable transceiver (100). Also, the particular harmonic selected for reception is 2 f₀ since it is generally understood that 2 f₀ is the strongest of the harmonics produced by a relevant target. Since the uncompensated RF output of a typical system-on-a-chip integrated circuit is below 1 mW, and since excitation of a nonlinear junction at standoff range typically requires a transmit power of greater than 10 mW, a power amplifier (PA) (120a, 120b) is placed between the RF source (118a, 118b) and the transmitting antenna (112, 114). Also, since the sensitivity of nonlinear detectors (134) must generally reach down to 200 fW, a low-noise amplifier (LNA) (136) is placed between the receiver antenna (116) and the RF detector (134). These features are illustrated in FIGS. 3A and 3B.

For nonlinear junction detection, two properties are highly desirable. These are linearity in the transmitter (106, 108) and sensitivity in the receiver (110). For harmonic NLJD, ideally the transmitter would emit RF power at f₀ and not at any harmonics, since harmonics emitted from the transmitter reflect from linear (clutter) items in the environment, are captured by the harmonic receiver, and generate false alarms. To eliminate such harmonics before they are emitted, a low-pass filter (LPF) (144a, 144b) is placed after the PA (120a, 120b) and before the Tx antenna (112, 114), as illustrated in FIG. 4A. Proper elimination of the system-generated harmonics requires terminating 2 f₀ instead of reflecting it back into the PA (120a, 120b). This linearization of the transmit signal may be accomplished by implementing a diplexer 172 as the LPF (144a, 144b), with its high-pass output terminated in a matched load (e.g. 50Ω).

Some portion of the transmitted probe signal at f₀ inadvertently couples directly from the Tx antenna (112, 114) to the Rx antenna (116). Also, linear targets in the environment will reflect f₀ back towards the receiver. In either case, the transmitted f₀ appears in the receive chain (140), and because the nonlinear responses of typical targets are so weak, the power received in front of the LNA (136) at f₀ is many orders of magnitude greater than the power received at 2 f₀. Front of the LNA refers to the side of the LNA closest to the Rx antenna, i.e. before the LNA in the direction from the Rx antenna to the detector. To avoid saturating the RF detector (134) with a strong f₀ which would mask a weak 2 f₀, a high-pass filter (HPF) (142) is placed in the receive chain (138) to pass 2 f₀ and attenuate f₀. The HPF is visible in FIG. 4B. Similar to the transmitter LPF, another diplexer (172) can be implemented as the receiver HPF; its low-pass output is terminated in a matched load such that f₀ does not re-reflect within the receiver to potentially generate additional harmonics. Accordingly, low-pass filtering is implemented in the transmitter to achieve maximum Tx (transmitter) linearity, and high-pass filtering is implemented in the receiver to achieve maximum Rx (receiver) sensitivity. If an appreciable bandwidth (e.g. 100 MHz or more) is to be swept for target responses, then the Tx low-pass filters and Rx high-pass filters must be carefully selected. To sweep an ultra-wide bandwidth, the NLJD must select from amongst a bank of LPFs and a bank of HPFs.

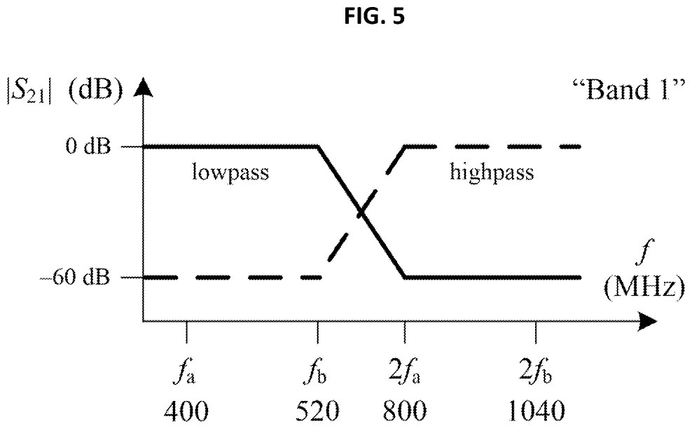

For any one LPF/HPF pair, the highest transmitted f₀ must not exceed the lowest received 2 f₀, otherwise the low-pass filter will not adequately eliminate the lowest 2 f₀'s produced by the PA and/or the high-pass filter will not adequately eliminate the highest f₀'s coupled into the receiver. The Tx and Rx bands cannot overlap, and there should be a sufficient guard-band between the two to achieve more than 60 dB of stop-band attenuation in each. FIG. 5 provides an illustration of the LPF/HPF requirements. FIG. 5 illustrates pass-bands and stop-bands for the low-pass filter(s) in the transmitter and the high-pass filter(s) in the receiver. Assuming that the desired transmit band extends from f₀=fₐ to f₀=f_{b}, the passband of the HPF must begin at/before 2fₐ, the stopband of the LPF must begin at/before 2fₐ, the stopband of the HPF must end at/after f_{b}, and f_{b} must be less than 2fₐ. In this example, fₐ=400 MHz and f_{b}=520 MHz.

To allow the Tx chain (122a, 122b) to achieve a transmit power greater than 1 W while incurring losses in the filters which establish acceptable linearity, the amplification should be split across at least two stages. A pre-amplifier (154a, 154b) is inserted before the power amplifier (120a, 120b) in the direction from the RF source to the Tx antenna, as shown in FIG. 6. Another LPF (144a, 144b) is inserted between the pre-amplifier and the power amplifiers to minimize 2 f₀ output by the pre-amplifier before the harmonic is re-generated by the power amplifier. As shown in FIG. 6, gain in the transmit path (124a, 124b) is split between a pre-amplifier and power amplifier. LPFs are inserted after each amplifier to achieve high power with high linearity.

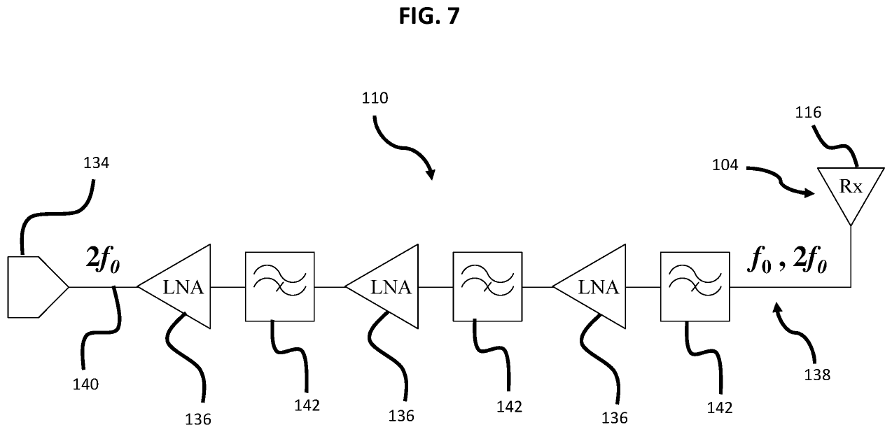

As shown in FIG. 7, gain in the receive path (140) is split across multiple (e.g. three) LNAs (136). High-pass filters (142) are inserted before each LNA (136) to eliminate f₀. In the Rx chain (138), the weak harmonic must be amplified to a level acceptable for capture and processing. Signals as weak as 10⁻¹³ W should be amplified to 1 mW or more to exploit the full range of bits available for digitization of the target response. A single-stage LNA (136) cannot achieve this degree of gain; thus, as in the transmitter, the gain is split across multiple stages. In FIG. 7, three stages of gain are realized between the Rx antenna (116) and the RF detector (134). As each LNA (136) may inadvertently amplify f₀, a high-pass filter (142) is inserted before each LNA (136) to block f₀ and ensure that only 2 f₀ is ultimately captured.

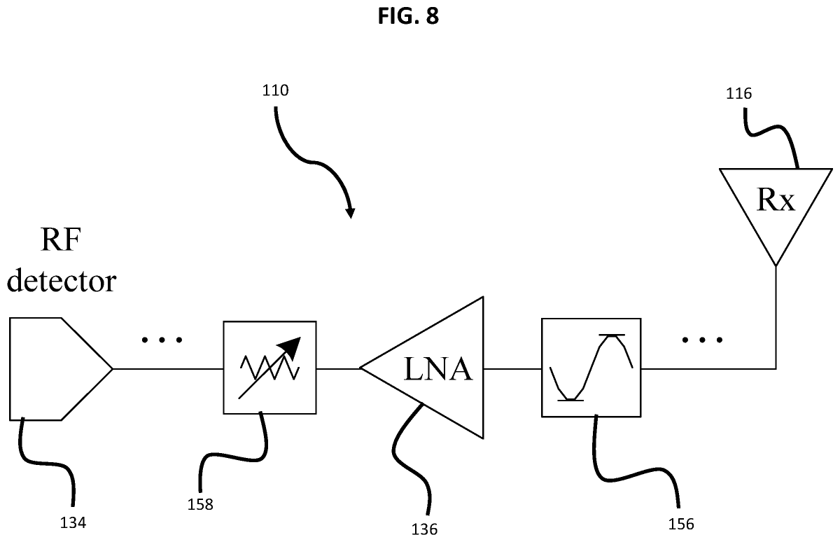

FIG. 8 shows a limiter placed before the LNA to prevent saturation, and an attenuator placed after the LNA to maximize the available range of voltages to be digitized by the detector. To prevent the saturation of any one LNA (136) in the receive chain (which can occur if a strong enough f₀ is received by the antenna, or if a strong enough f₀ couples to another portion of the receive chain closer to the RF detector, or if interference within the operational band of the LNAs is picked up by the Rx antenna), limiters (156) are placed before each LNA. Also, to maximize the range of voltages that will be digitized by the RF detector (i.e. to minimize quantization error), the gain of each stage may be adjusted by placing a variable attenuator (158) after each LNA. A single limiter-and-attenuator pair straddling an LNA is shown in FIG. 8.

For narrowband transmit signals (such as constant-amplitude sinusoids used for basic detection), an additional technique can be grafted onto passive filtering to further attenuate a particular harmonic (in this case 2 f₀). The technique is called feed-forward filter reflection (FFFR). It is a variation of feed-forward cancellation, which combines an undesired signal (in this case, the PA-generated 2 f₀) with a matched-amplitude but out-of-phase version of itself. When the signals from the two paths add, the undesired signal is cancelled before it is transmitted to the following stage. The FFFR technique is shown in U.S. Pat. No. 10,018,707, which is incorporated by reference herein in its entirety.

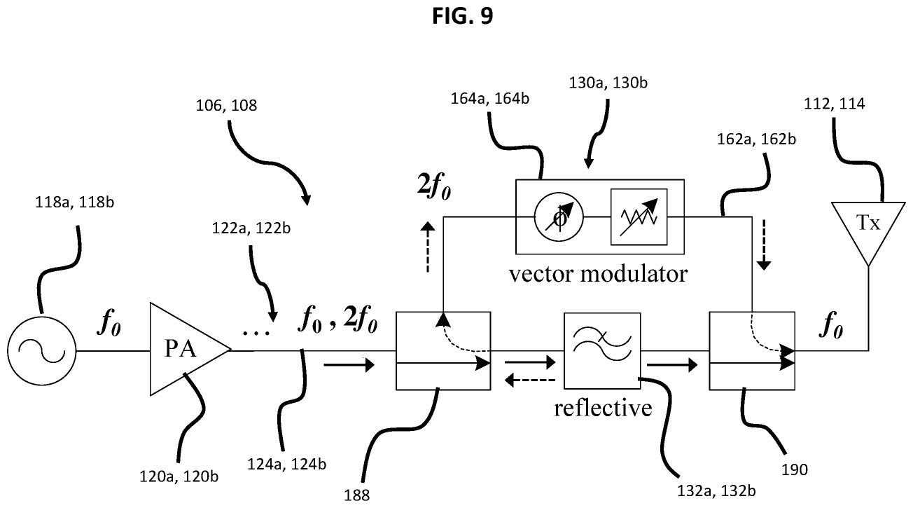

The FFFR technique is added to the transmitter (106, 108) in FIG. 9. Some amount of 2 f₀ remains after the PA (and after low-pass filtering the Tx signal as discussed previously). Another filter, this time a reflective low-pass filter (132a, 132b), is placed before the Tx antenna. A directional coupler (188) is inserted before the filter (132a, 132b) to sample some of the 2 f₀ reflected backwards from this filter. A vector modulator (tuner 164a, 164b) adjusts the amplitude and phase of this sampled harmonic to match it to the 2 f₀ that would have arrived at the Tx antenna without insertion of this hardware (FFFR device 130a, 130b). This adjusted harmonic is, ideally, equal in amplitude and 180° out-of-phase with the harmonic passing through the reflective filter. The directional coupler (190) between the reflective filter and Tx antenna combines the sampled-and-adjusted 2 f₀ to the very small amount of 2 f₀ output from the reflective filter. In principle, the FFFR technique completely eliminates 2 f₀ at the input to the Tx antenna. Cancellation of approximately 10 dB may be achieved with minimal tuning of the vector modulator (164a, 164b). Over 100 dB of cancellation may be achieved by iteratively correcting the feed-forward path.

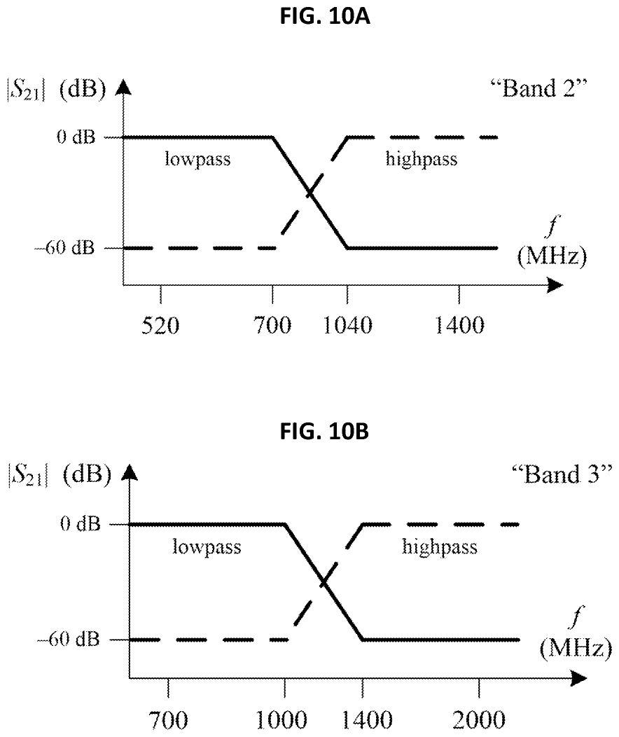

Experiments show that targets-of-interest respond to transmit frequencies between f₀=400 MHz and f₀=1000 MHz. To satisfy the aforementioned condition that the bands for f₀ and 2 f₀ do not overlap, this wide transmit band is broken into separate sub-bands, also referred to herein as the plurality of transmit bands, whose low-pass filters each cover a portion of the overall wide band. FIGS. 10A and 10B illustrate two additional filter sub-bands which, in addition to the example of FIG. 5, span a continuum of transmit frequencies from 400 to 1000 MHz. FIGS. 10A and 10B illustrate pass-bands and stop-bands for sets of LPFs and HPFs corresponding to two additional sub-bands or transmit bands: (a) f₀=520 to 700 MHz and (b) f₀=700 to 1000 MHz.

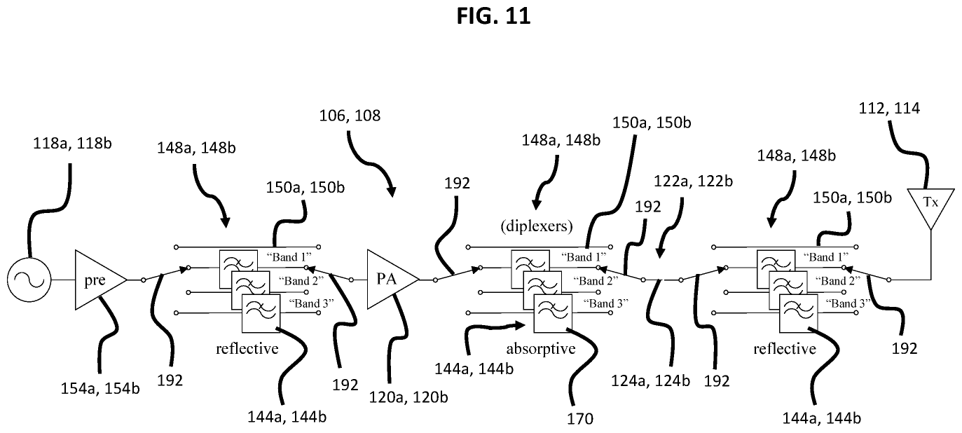

As shown in FIG. 11, switches before and after each low-pass filter allow the transmitter to select from amongst multiple bands of frequencies (or to amplify without filtering). To accomplish multiple stages of filtering while selecting between these different bands (as certain targets might respond more strongly within particular sub-bands), switches (192) are placed along the Tx chain. Three pairs of switches (192) which allow the transmitter to be configured across three banks of filters are shown in FIG. 11. In accordance with the illustrated embodiment of FIG. 11, each bank contains three filters (“Band 1”, “Band 2” and “Band 3” corresponding to the labels in FIGS. 5 and 10) and a direct-connect “through” path to allow for testing of the amplifiers alone and/or completely swapping in/out filter stages.

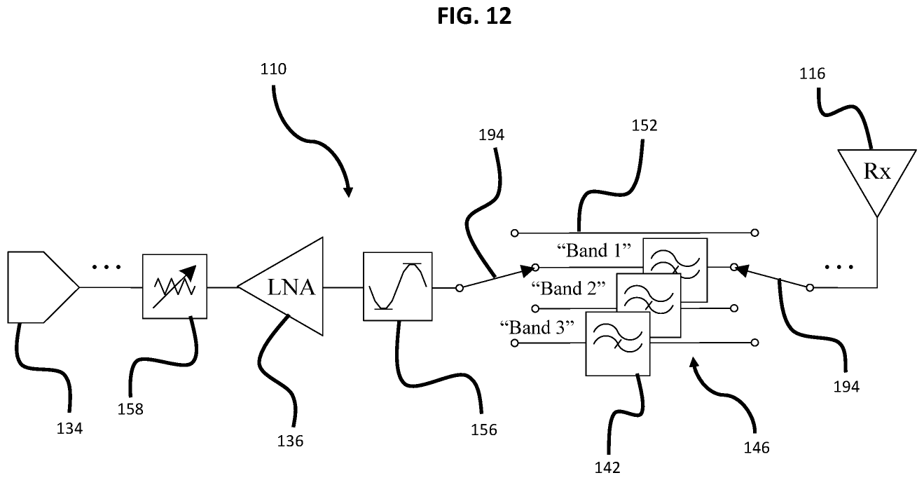

Each low-pass transmit band (e.g. 400 MHz<f₀<520 MHz) maps to a high-pass receive band (e.g. 800 MHz<2f₀<1040 MHz). Thus, in the receiver, banks of filters are inserted before each LNA (136), as illustrated in FIG. 12. As illustrated in FIG. 12, switches (194) before and after each bank (146) of high-pass filters (142) allow the receiver to select from amongst multiple bands of frequencies. Each high-pass filter (142) band in the receiver corresponds to a low-pass band in the transmitter.

Additional spectral content may be generated from a nonlinear target if it is illuminated by multiple frequencies, simultaneously. For intermodulation detection, two frequencies f₁ and f₂ (usually of equal amplitude) are transmitted to the target. The same phenomenon which generates harmonics under illumination by a single frequency generates integer-multiple summations of f₁ and f₂. The most commonly received intermodulation frequencies are 2f₁-f₂ and 2f₂-f₁ as those are nearest to the transmitted f₁ and f₂; similar antennas may be used to transmit and receive as both sets of frequencies are within the same band.

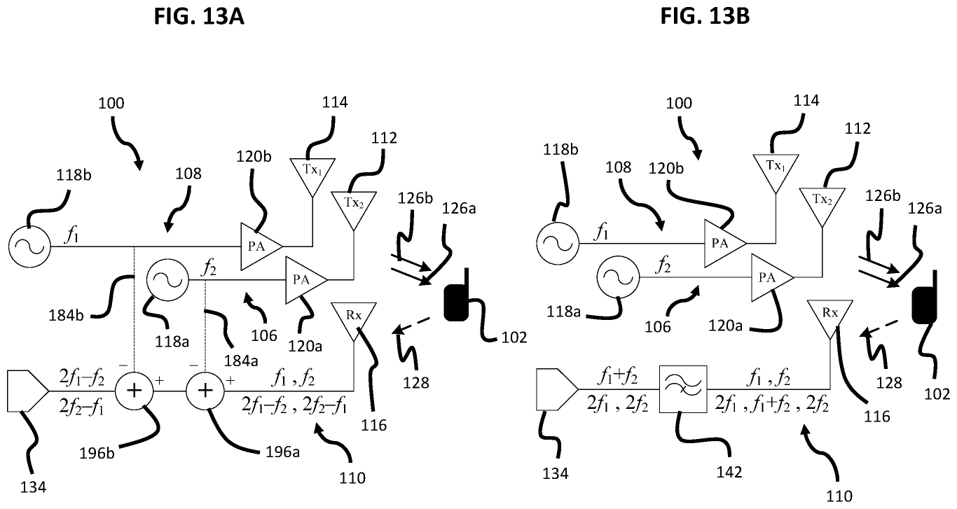

FIGS. 13A and 13B illustrate two additional modes-of-operation, in which multiple frequencies (f₁, f₂) are simultaneously transmitted. These modes are (a) intermodulation and (b) cross-modulation. The basic operation of the transceiver (100) configured in intermodulation mode is shown in FIG. 13A. Two physically-separate (isolated) transmitters (106, 108) generate each probe (f₁, f₂) because applying both frequencies simultaneously to the input of the same PA (120a, 120b) would generate intolerable distortion. The PA would output its own intermodulation, and such intermodulation cannot be eliminated by passive hardware filtering because the intermodulation frequencies are so close to the desired transmit frequencies. A typical tone spacing is f₂-f₁=1 MHz. For the intermodulation mode, feed-forward cancellation is implemented, using the source output signals of the transmitters (106, 108), to drive linear target responses below the nonlinear target responses to avoid saturating the receiver detector (134). This form of cancellation (in contrast with FFFR) requires routing f₁ and f₂ from each transmitter to the receiver (110).

A combination of multiple transmit frequencies and harmonic reception is illustrated in FIG. 13B. In this configuration, the system receives cross-modulation: integer summations of f₁ and f₂ in the same band as 2 f₁ and 2f₂ rather than near the original f₁ and f₂. This cross-modulation (or multitone-harmonic) mode implements passive (high-pass) filtering in the receiver to eliminate the Tx-to-Rx-coupled (or linearly-reflected) f₁ and f₂. Also, this mode uses multiple isolated transmitters (106, 108) to minimize system-generated cross-modulation, although Tx₁ (106) will emit a small amount of 2f₁ even after filtering (and FFFR) and Tx₂ (108) will emit a small amount of 2f₂, the system will not emit f₁+f₂. Because the two frequencies are generated by physically separate transmit chains, they do not interact inside the transmitter. Interaction of the two frequencies occurs at the target only; thus, the presence of f₁+f₂ (even in the presence of system-generated 2f₁ and 2f₂) indicates target detection.

FIG. 14 shows a reconfigurable transceiver 100 with four possible modes-of-operation: linear, harmonic, intermodulation, and cross-modulation. All four modes-of-operation (linear, harmonic, intermodulation, cross-modulation) are selectable in the system (100) constructed according to FIG. 14. Observable in this diagram are two transmitters (106, 108) and a single receive chain (138). Each transmitter (and the receiver) may select from amongst three sets of filters and a direct pass-through path. FFFR is implemented in each transmitter, and a feed-forward cancellation path is provided from each transmitter to the receiver.

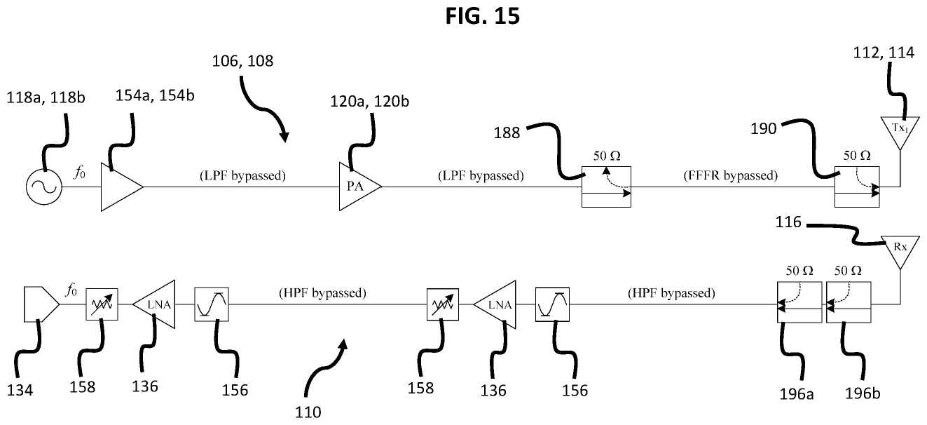

When all filter banks are bypassed, as shown in FIG. 15, the system is configured for linear transmission and reception, i.e. the transceiver (100) is configured in the linear mode. A single transmitter (106 or 108) is active. The coupled port of each directional coupler (188, 190, 196a, 196b) is terminated in a matched load such that each coupler acts as a pass-through component. The system transmits f₀ and receives f₀ from the target.

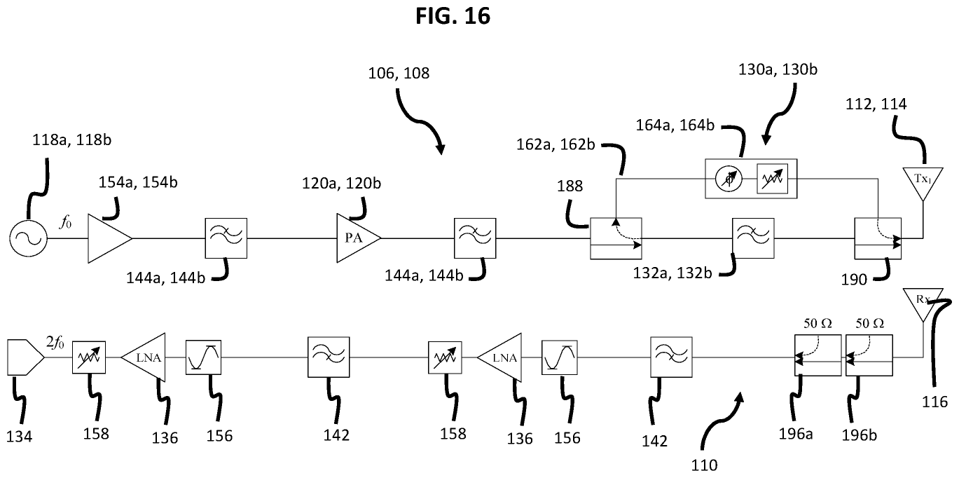

When a single set of filters is selected (for the Tx and Rx) and a single transmitter is active, the transceiver (100) operates in the harmonic mode. This configuration is shown in FIG. 16. The system transmits f₀ and receives 2 f₀ from the target.

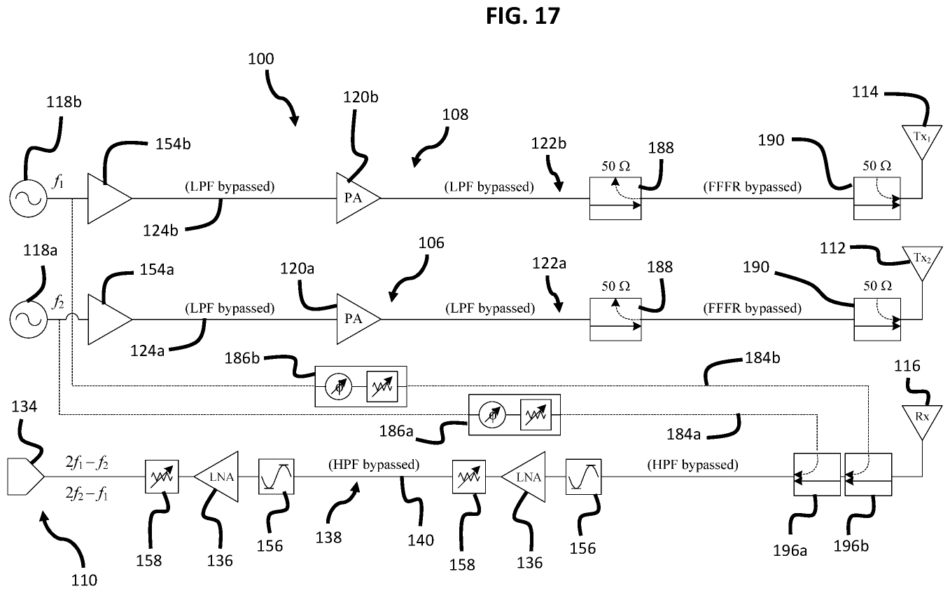

When two transmitters are active and feed-forward cancellation is routed from the transmitters to the receivers, the system is configured in intermodulation mode as illustrated in FIG. 17. The filters are bypassed and the couplers in the transmitters are in pass-through configuration (as FFFR is inactive). The system transmits f₁ and f₂ and receives 2f₁-f₂ and/or 2f₂-f₁ from the target.

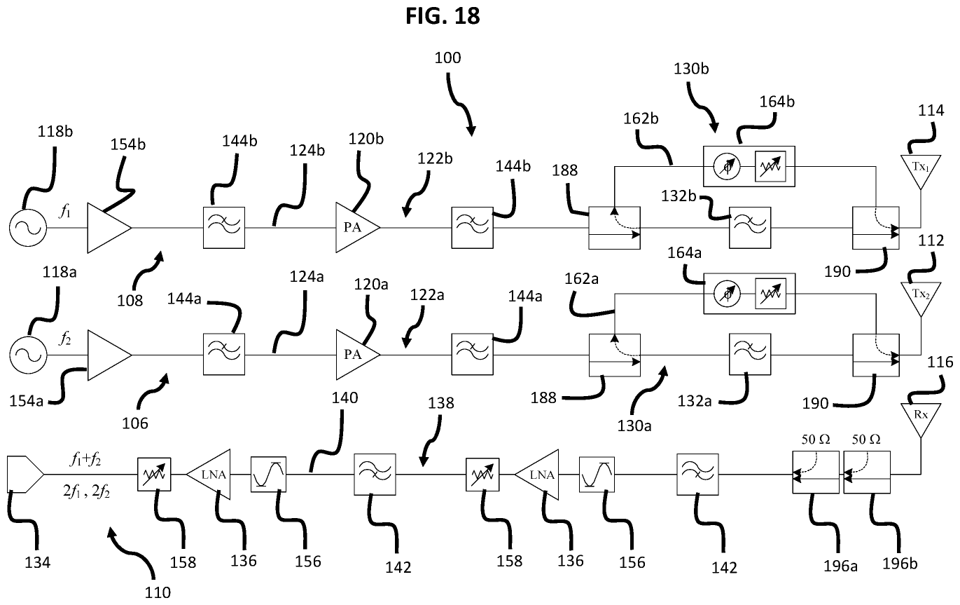

When both transmitters are active but no feed-forward cancellation exists between the transmitters (Tx₁, Tx₂) and the receiver (Rx, 110) the system is in cross-modulation mode. This configuration is shown in FIG. 18. The system transmits f₁ and f₂ and receives f₁+f₂ (as well as 2 f₁ and 2 f₂) from the target.

The foregoing description of the specific embodiments will so fully reveal the general nature of the embodiments herein that others may, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein may be practiced with modification within the spirit and scope of the appended claims.

What is claimed is:

1. An apparatus for detection of one or more target objects, the apparatus comprising:
an antenna structure;
at least one transmitter communicating with the antenna structure, the at least one transmitter being configured to generate a transmitted signal that is transmitted by the antenna structure; and
at least one receiver communicating with the antenna structure, the at least one receiver being configured to receive a received signal emanating from the one or more target objects in response to the transmitted signal and that is received by the antenna structure,
wherein the apparatus operates in one of four selectable modes of operation selected from the group consisting of linear mode, harmonic mode, intermodulation mode, and cross-modulation mode, and is configured to be switchable from one of the modes to another one of the modes.

2. The apparatus of claim 1, wherein the at least one transmitter comprises:
a radio frequency source configured to output a radio frequency source output signal to a transmit signal chain that begins with the radio frequency source and ends with the antenna structure, the transmit signal chain providing a transmit signal path from the radio frequency source to the antenna structure for a transmit signal, the transmit signal chain providing for signal communication between the radio frequency source and the antenna structure, wherein the source output signal is amplified with a gain needed to generate an antenna input transmit signal that is provided to the antenna structure; and
at least one power amplifier provided in the transmit signal chain and configured to amplify the source output signal to provide at least a portion of the gain needed to generate the antenna input transmit signal that is provided to the antenna structure to thereby generate the transmitted signal, and
wherein the at least one receiver comprises:
a radio frequency detector having at least one input configured to receive a detector input signal derived from the received signal received by the antenna structure, wherein a receive signal chain provides a receive signal path from the antenna structure to the detector for a receive signal; and
at least one low-noise amplifier provided in the receive signal chain and configured to amplify a low-noise amplifier input signal derived from the received signal received by the antenna structure, the low-noise amplifier producing a low-noise amplifier output signal, which is provided to the receive signal chain such that the detector input signal can be derived from the low-noise amplifier output signal.

3. The apparatus of claim 2, wherein the at least one receiver further comprises:
at least one high-pass filter provided such that the receive signal path in the receive signal chain can be selectively routed through the high-pass filter, the high-pass filter being configured to filter the low-noise amplifier input signal derived from the received signal received by the antenna structure.

4. The apparatus of claim 3, wherein the power amplifier has an input signal and an output signal and wherein the at least one transmitter further comprises:
at least one low-pass filter provided such that the transmit signal path in the transmit signal chain can be selectively routed through the low-pass filter, the low-pass filter being configured to filter the power amplifier output signal derived from the source output signal.

5. The apparatus of claim 2, wherein the at least one receiver further comprises:
at least one bank of high-pass filters comprising a plurality of high-pass filters provided such that the receive signal path in the receive signal chain can be selectively routed through a selected one of the plurality of high-pass filters, each of the plurality of high-pass filters being configured to filter the low-noise amplifier input signal derived from the received signal received by the antenna structure when it is selected such that the receive signal path is routed through it.

6. The apparatus of claim 5, wherein the power amplifier has an input signal and an output signal and wherein the at least one transmitter further comprises:
at least one bank of low-pass filters comprising a plurality of low-pass filters provided such that the transmit signal path in the transmit signal chain can be selectively routed through a selected one of the plurality of low-pass filters, each of the plurality of low-pass filters being configured to filter the power amplifier output signal derived from the source output signal when it is selected such that the transmit signal path is routed through it.

7. The apparatus of claim 6, wherein each of the plurality of low-pass filters corresponds to a corresponding one of the plurality of high-pass filters, wherein each of the plurality of high-pass filters corresponds to a corresponding one of the plurality of low-pass filters, wherein each of the plurality of high-pass filters and the corresponding one of the plurality of low-pass filters form a pair of corresponding high-pass and low-pass filters, wherein each of the plurality of low-pass filters passes frequencies in a corresponding transmit band of a plurality of transmit bands, wherein each of the plurality of high-pass filters effectively rejects frequencies in the corresponding transmit band of the plurality of transmit bands corresponding to the corresponding one of the plurality of low-pass filters such that the frequency of the transmitted signal that is transmitted by the antenna structure can be scanned over the plurality of transmit bands by switching from one pair of corresponding high-pass and low-pass filters corresponding to one of the plurality of transmit bands to another pair of corresponding high-pass and low-pass filters corresponding to another one of the plurality of transmit bands.

8. The apparatus of claim 7, wherein the at least one bank of low-pass filters further comprises a transmit signal bypass path to allow the plurality of low-pass filters to be selectively bypassed by the transmit signal path by selectively routing the transmit signal through the transmit signal bypass path, and
wherein the at least one bank of high-pass filters further comprises a receive signal bypass path to allow the plurality of high-pass filters to be selectively bypassed by the receive signal path by selectively routing the receive signal through the receive signal bypass path.

9. The apparatus of claim 8, wherein the at least one transmitter further comprises a plurality of transmit chain amplifiers connected in series in the transmit signal chain, each of the plurality of transmit chain amplifiers having an input for receiving a transmit chain amplifier input signal, each of the plurality of transmit chain amplifiers having an output for outputting a transmit chain amplifier output signal, each of the plurality of transmit chain amplifiers having a gain, wherein the plurality of transmit chain amplifiers includes a first transmit chain amplifier and a last transmit chain amplifier, wherein the first transmit chain amplifier receives the source output signal at its input, wherein the last transmit chain amplifier has its transmit chain amplifier output signal routed to the antenna structure, wherein the transmit chain amplifier input signal of each of the plurality of transmit chain amplifiers is derived from the transmit chain amplifier output of a preceding one of the plurality of transmit chain amplifiers except for the first transmit chain amplifier, wherein the first transmit chain amplifier is a pre-amplifier, wherein the power amplifier is the last transmit chain amplifier, and wherein the plurality of transmit chain amplifiers provide the gain needed to generate the antenna input transmit signal.

10. The apparatus of claim 9, wherein the at least one receiver further comprises a plurality of receive chain amplifiers connected in series in the receive signal chain, each of the plurality of receive chain amplifiers having an input for receiving a receive chain amplifier input signal, each of the plurality of receive chain amplifiers having an output for outputting a receive chain amplifier output signal, each of the plurality of receive chain amplifiers having a gain, wherein the plurality of receive chain amplifiers includes a first receive chain amplifier and a last receive chain amplifier, wherein the receive chain amplifier input signal of the first receive chain amplifier is derived from the received signal received by the antenna structure, wherein the last receive chain amplifier has its receive chain amplifier output signal routed to the radio frequency detector, wherein the receive chain amplifier input signal of each of the plurality of receive chain amplifiers is derived from the receive chain amplifier output of a preceding one of the plurality of receive chain amplifiers except for the first receive chain amplifier, wherein the first receive chain amplifier is the low-noise amplifier, wherein the plurality of receive chain amplifiers are all low-noise amplifiers, and wherein the plurality of receive chain amplifiers provide a gain needed to amplify the received signal received by the antenna structure such that the radio frequency detector can detect the received signal.

11. The apparatus of claim 10, wherein the at least one transmitter comprises a plurality of banks of low-pass filters, each bank of low-pass filters being configured to selectively filter the transmit chain amplifier output signal of a corresponding one of the plurality of transmit chain amplifiers, each bank of low-pass filters being provided in the transmit chain between the output of the corresponding one of the plurality of transmit chain amplifiers and the input of the succeeding one of the plurality of transmit chain amplifiers except for the last transmit chain amplifier, which has its corresponding bank of low-pass filters provided between the output of the last transmit chain amplifier and the antenna structure.

12. The apparatus of claim 11, wherein the at least one receiver comprises a plurality of banks of high-pass filters, each bank of high-pass filters being configured to selectively filter the receive chain amplifier input signal of a corresponding one of the plurality of receive chain amplifiers, each bank of high-pass filters being provided in the receive chain between the input of the corresponding one of the plurality of receive chain amplifiers and the output of the preceding one of the plurality of receive chain amplifiers except for the first receive chain amplifier, which has its corresponding bank of high-pass filters provided between the input of the first receive chain amplifier and the antenna structure.

13. The apparatus of claim 12, further comprising:
a corresponding limiter provided before the input of each of the plurality of receive chain amplifiers, in the direction from the antenna structure to the radio frequency detector in the receive chain, to prevent saturation of each of the plurality of receive chain amplifiers; and
a corresponding attenuator placed after the output of each of the plurality of receive chain amplifiers, in the direction from the antenna structure to the radio frequency detector in the receive chain, to maximize the available range of voltages to be detected by the radio frequency detector.

14. The apparatus of claim 13, wherein the at least one transmitter further comprises:
a feed-forward filter reflection device provided in the transmit chain to further diminish the significance of undesirable frequencies in the antenna input transmit signal that is provided to the antenna structure, the feed-forward filter reflection device is provided in the transmit chain between the bank of low-pass filters corresponding to the last transmit chain amplifier, which is provided after the output of the last transmit chain amplifier, and the antenna structure,
wherein the bank of low-pass filters corresponding to the last transmit chain amplifier has an input and an output, and wherein the feed-forward filter reflection device comprises:
at least one bank of low-pass filters comprising a plurality of low-pass filters provided such that the transmit signal path in the transmit signal chain can be selectively routed through a selected one of the plurality of low-pass filters, each of the plurality of low-pass filters being configured to filter the transmit signal from the output of the bank of low-pass filters corresponding to the last transmit chain amplifier derived from the source output signal when it is selected such that the transmit signal path is routed through it;
a transmit signal bypass path to allow the plurality of low-pass filters of the feed-forward filter reflection device to be selectively bypassed by the transmit signal path by selectively routing the transmit signal through the transmit signal bypass path of the feed-forward filter reflection device; and
a feed-forward path routing a signal reflected by the bank of low-pass filters of the feed-forward filter reflection device, which contains the undesirable frequencies, around the bank of low-pass filters of the feed-forward filter reflection device such that the signal reflected by the bank of low-pass filters of the feed-forward filter reflection device rejoins the transmit signal path from the output of the bank of low-pass filters of the feed-forward filter reflection device for destructive interference with the undesirable frequencies in the transmit signal from the output of the bank of low-pass filters of the feed-forward filter reflection device before the transmit signal path reaches the transmit signal input of the antenna structure.

15. The apparatus of claim 14, wherein the feed-forward path is provided with a tuner for tuning the feed-forward filter reflection device to enhance the destructive interference between the undesirable frequencies in the signal reflected by the bank of low-pass filters of the feed-forward filter reflection device and the undesirable frequencies in the transmit signal from the output of the bank of low-pass filters of the feed-forward filter reflection device.

16. The apparatus of claim 2, wherein the at least one transmitter further comprises:
at least one low-pass filter provided in the transmit signal path between the power amplifier and the antenna structure such that the transmit signal path in the transmit signal chain can be routed through the low-pass filter, the low-pass filter being configured to filter undesirable frequencies out of the transmit signal in the transmit signal path traveling to the antenna structure, wherein the low-pass filter is an absorptive filter that squelches the undesirable frequencies.

17. The apparatus of claim 2, wherein the at least one receiver further comprises:
at least one high-pass filter provided in the receive signal path between the low-noise amplifier and the antenna structure such that the receive signal path in the receive signal chain can be routed through the high-pass filter, the high-pass filter being configured to filter undesirable frequencies out of the receive signal in the receive signal path traveling from the antenna structure to the low-noise amplifier, wherein the low-pass filter is an absorptive filter that squelches the undesirable frequencies.

18. The apparatus of claim 2, further comprising:
an intermodulation signal path configured to selectively connect the radio frequency source output signal of the transmitter to the receive signal path of the receiver between the antenna structure and the low-noise amplifier, the intermodulation signal path being configured to allow the use of the radio frequency source output signal for cancellation of undesirable frequencies in the receive signal in the receive signal path traveling from the antenna structure to the low-noise amplifier; and
a tuner provided in the intermodulation signal path.

19. The apparatus of claim 18, wherein the at least one transmitter is one of a plurality of transmitters, each of the plurality of transmitters having a radio frequency source output signal that is of a different frequency compared to other transmitters of the plurality of transmitters, and wherein each of the plurality of transmitters has the same categories of components and the same transmit chain layout and the same intermodulation signal path layout as the at least one transmitter.

20. The apparatus of claim 15, wherein the at least one transmitter is one of a plurality of transmitters, each of the plurality of transmitters having a radio frequency source output signal that is of a different frequency compared to other transmitters of the plurality of transmitters, and wherein each of the plurality of transmitters has the same categories of components and the same transmit chain layout and the same transmit signal path layout as the at least one transmitter.
